(19) United States
(12) Patent Application Publication
(10) Pub. No.: US 2006/0091421 A1
(43) Pub. Date: May 4, 2006

(54) Semiconductor laser device

(75) Inventors: Kenichi Ono, Tokyo (JP); Masayoshi Takemi, Tokyo (JP)

Correspondence Address: LEYDIG VOIT & MAYER, LTD, 700 THIRTEENTH ST. NW, SUITE 300, WASHINGTON, DC, 20005-3960, US

(73) Assignee: Mitsubishi Denki Kabushiki Kaisha, Tokyo (JP)

(21) Appl. No.: 11/175,379

(22) Filed: Jul. 7, 2005

(30) Foreign Application Priority Data
Oct. 28, 2004 (JP) 2004-314522

(51) Int. Cl. H01L 31/109

(52) U.S. Cl. 257/200

(57) ABSTRACT

A semiconductor laser device according to the present invention comprises: an n-band discontinuity reduction layer (n-BDR layer) disposed on an n-GaAs substrate and the n-BDR layer including an AlGaAs layer whose concentration of Si doped as an n-type impurity is in a range from 0.2×10¹⁸ cm⁻³ to 1.4×10¹⁸ cm⁻³; an n-type cladding layer of AlGaInP disposed on the n-BDR layer; an active layer including a quantum well disposed on the n-type cladding layer; and a p-type cladding layer of AlGaInP disposed on the active layer.

### BACKGROUND OF THE INVENTION

1. Field of the Invention

The present invention relates to a semiconductor laser device, especially a semiconductor laser device for an information communication apparatus.

2. Description of the Related Art

In recent years, broadband optical communication has progressed, a public communication network using an optical fiber has spread, and accordingly there has been an increasing demand for inexpensive transmitting of a large amount of information. Therefore, an amount of information handled by the information communication apparatus becomes enormous, and there is a demand for a highly reliable and inexpensive information communication capable apparatus of handling a large capacity of information at a high speed.

As to a semiconductor laser device which is a main component of the information communication apparatus, there has been a demand for a high-output semiconductor laser device by which highly efficient laser oscillation is possible and which has a high efficiency.

In recent years, there has been an increasing demand for a DVD-R/RW device which is one of high-speed large-capacity storage devices. High-output semiconductor laser (red laser whose emission wavelength is in the vicinity of 650 nm) is used in the DVD-R/RW device, and development of semiconductor laser has been advanced for high-speed processing of the information. The laser has a high efficiency, and an AlGaInP/GaAs-based material is used in the laser.

A conventional semiconductor laser device has a stacked structure of layers successively formed on an n-type GaAs substrate (hereinafter “n-type” is referred to as “n-”, “p-type” is referred to as “p-”, and “i-” is used when any impurities are not added) by an MOCVD process or the like. The layers include successively on the n-GaAs substrate: an n-GaAs first buffer layer; an n-AlGaAs second buffer layer; an n-AlGaInP cladding layer; an i-AlGaInP light guide layer; an active layer having a structure of multiple quantum wells (hereinafter abbreviated as “MQW”) comprising an i-AlGaInP barrier layer and a GaInP well layer; an i-AlGaInP light guide layer; a first p-AlGaInP cladding layer; a p-GaInP etching stopper layer (hereinafter referred to as the ESL layer); a second p-AlGaInP cladding layer; a p-GaInP band discontinuity reduction layer (hereinafter referred to as the BDR layer); and a p-GaAs cap layer. A window layer is disposed in the vicinity of front and rear end faces of an optical waveguide including an active layer, and the window layer is obtained by disordering a well layer of the active layer by diffusion of Zn. The second p-AlGaInP cladding layer, p-BDR layer of p-GaInP, and p-GaAs cap layer form striped ridges. An n-electrode is disposed on the back surface of the n-GaAs substrate, and a p-electrode is disposed on a p-GaAs cap layer.

In the semiconductor layer, the n-AlGaAs second buffer layer is disposed because Zn not only disorders the well layer of the active layer but also diffuses on the side of the n-GaAs substrate in forming the window layer. If the n-AlGaAs second buffer layer is not disposed, Zn diffuses even to the n-GaAs buffer layer, a p-n bonding is formed in the n-GaAs buffer layer, and this causes a current leak. To prevent this, the n-AlGaAs second buffer layer is disposed because Zn does not easily diffuse in n-AlGaAs (see, e.g., Japanese Patent Application Laid-Open No. 2003-31901 [0031]).

Moreover, there is not any limitation to the constitution having the window layer. As another constitution, band discontinuity reduction layers are sometimes disposed on not only a p-side but also an n-side in order to reduce a resistance value of an non-ohmic resistance component attributable to a difference of band gap energy between the n-AlGaInP cladding layer and the n-GaAs substrate. In this case, as compared with the use of an AlGaInP (or GaInP) material only, by the use of an AlGaAs material, it is possible to more effectively reduce a large difference of band gap energy between AlGaAs and GaAs.

Moreover, in a known document, a constitution of semiconductor laser is described in which AlGaInP-based n-type and p-type cladding layers are constituted with an optimum carrier concentration, Se is used as n-type impurities in order to realize enhancement of PL emission intensity, reduction of a threshold value, and lengthening of life, and an n-type carrier concentration of the n-type cladding layer is set to 2 to 3×10¹⁷ cm⁻³ (see, e.g., Japanese Patent Application Laid-Open No. Hei 3-276785, 526 pages (pages 5 and 6)).

Furthermore, as another constitution of the semiconductor laser device in a known document, a constitution is described in which n-GaAs buffer layer, and an n-In0.5(Ga0.3Al0.7)0.5P cladding layer (doped with Si: 3 to 5×10¹⁷ cm⁻³) are disposed on an n-GaAs substrate (see, e.g., Japanese Patent Application Laid-Open No. Hei 4-14277, the upper right column of page 506).

Additionally, as another constitution of the semiconductor laser device in a known document, a constitution is described comprising: an n-GaAs buffer layer; and an n-AlGaInP optical waveguide layer having a carrier concentration of 5×10¹⁷ cm⁻³ to 1×10¹⁸ cm⁻³ on an n-GaAs substrate (see, e.g., Japanese Patent Application Laid-Open No. Hei 10-290049, [0011]).

Moreover, as a method of manufacturing a semiconductor device, which is capable of suppressing diffusion of a p-type dopant into an active layer and obtaining a desired semiconductor device with good reproducibility, in a known document, a method of manufacturing semiconductor laser is described including a step of crystal-growing a layer formed of bisethylcyclopentadieniel magnesium which is a p-type doping material. In this method of manufacturing the semiconductor laser, it is described that an n-GaAs buffer layer, and an n-(Al0.7Ga0.3)0.5In0.5P cladding layer having a n-type impurity concentration of 4×10¹⁷ cm⁻³ are formed on an n-GaAs substrate. Additionally, there is not any description as to a reason why the impurity concentration of the n-cladding layer is selected (see, e.g., Japanese Patent Application Laid-Open No. Hei 10-190145, [0011]).

However, when the n-AlGaAs layer is usually disposed in order to prevent a drop of a forward-direction rising voltage Vf of the semiconductor laser, an Al composition ratio x of about 0.5 is used with respect to AlxGa1-xAs constituting this n-AlGaAs layer.

Moreover, even when the AlGaAs layer is disposed as a band discontinuity reduction layer, the Al composition ratio x is raised and used with respect to AlxGa1-xAs of the AlGaAs layer.

When AlGaAs having a high Al composition ratio in this manner is doped with Si, a carrier activation ratio of an Si dopant is about 40 to 50%, and in the conventional semiconductor laser, the carrier concentration of the n-AlGaAs second buffer layer is usually set, for example, to about 1.0×10¹⁸ cm⁻³ to 1.5×10¹⁸ cm⁻³ (m10ⁿ will be hereinafter represented by mEn. For example, “5×10¹⁷” will be represented by 5E17) in the same manner as in the n-GaAs substrate or the n-GaAs first buffer layer. This corresponds to an Si concentration of about 1.5E18 cm⁻³ to 2.3E18 cm⁻³.

Furthermore, the Al composition ratio is set to be comparatively high in order to sufficiently secure a band gap difference between the n-AlGaInP cladding layer and the active layer. For example, in notation of (AlxGa1-x)In1-yPy, an Al composition ratio x of about 0.7 is used. The carrier concentration of the n-AlGaInP cladding layer is usually set to be high to a certain degree in order to prevent an element resistance from being influenced by the concentration, and the concentration is, for example, about 0.5E18 cm⁻³ to 1.5E18 cm⁻³. The corresponding Si concentration of the n-AlGaInP cladding layer is about 0.6E18 cm⁻³ to 1.7E18 cm⁻³.

In the semiconductor laser comprising the n-AlGaAs layer or an n-AlGaInP cladding layer doped with Si and having a high carrier or Si concentration, an operating current sometimes increases.

The increase of the operating current in the semiconductor laser deteriorates properties at room temperature to lower efficiency, and further results in degradation of high-temperature and high-output operation and reliability.

### SUMMARY OF THE INVENTION

The present invention has been made in order to solve the above-described problem, and it is an object of the invention to provide a semiconductor laser device having a small operating current, high efficiency, and high reliability in a case where Si is used as an n-type dopant.

According to one aspect of the invention, there is provided a semiconductor laser device comprising: a GaAs substrate; an n-type semiconductor layer structure disposed on the GaAs substrate, including an AlGaAs layer doped with n-type impurities of Si, the AlGaAs layer having a concentration of Si in a range of 0.2×10¹⁸ cm⁻³ or more and 1.4×10¹⁸ cm⁻³ or less; an n-type cladding layer of AlGaInP disposed on the n-type semiconductor layer structure; an active layer disposed on the n-type cladding layer, and including a quantum well; and a p-type cladding layer of AlGaInP disposed on the active layer.

Accordingly, in the semiconductor laser device according to the present invention, in the n-AlGaAs layer any inactive Si atom is not formed that does not contribute as the carrier. Less atoms of the group 3 are kicked out of the n-AlGaAs layer by the inactive Si atoms, and the inactivation is inhibited with respect to the p-type impurities of the p-type layer by the atoms of the group 3 between the lattices.

Therefore, an operating current is retained at a low value, a property at room temperature becomes satisfactory, and a high-efficiency operation is possible. Consequently, there can be provided a semiconductor laser device by which a satisfactory high-temperature and high-output operation is possible and whose reliability is high.

According to another aspect of the invention, there is provided a semiconductor laser device comprising: a GaAs substrate; an n-type semiconductor layer structure disposed on the GaAs substrate, including an AlGaAs layer doped with n-type impurities of Si, the AlGaAs layer having n-type carrier concentration in a range of 1×10¹⁷ cm⁻³ or more and 9×10¹⁷ cm⁻³ or less; an n-type cladding layer of AlGaInP disposed on the n-type semiconductor layer structure; an active layer disposed on the n-type cladding layer, and including a quantum well; and a p-type cladding layer of AlGaInP disposed on the active layer.

Accordingly, in the semiconductor laser device according to the present invention, in the n-AlGaAs layer any inactive Si atom is not formed that does not contribute as the carrier. Less atoms of the group 3 are kicked out of the n-AlGaAs layer by the inactive Si atoms, and the inactivation is inhibited with respect to the p-type impurities of the p-type layer by the atoms of the group 3 between the lattices.

Therefore, an operating current is retained at a low value, a property at room temperature becomes satisfactory, and a high-efficiency operation is possible. Consequently, there can be provided a semiconductor laser device by which a satisfactory high-temperature and high-output operation is possible and whose reliability is high.

According to still another aspect of the invention, there is provided a semiconductor laser device comprising: a GaAs substrate; an n-type semiconductor layer structure disposed on the GaAs substrate; an n-type cladding layer of AlGaInP including n-type impurities of Si disposed on the n-type semiconductor layer structure, the n-type cladding layer having a concentration of Si in a range of 0.6×10¹⁷ cm⁻³ or more and less than 3.3×10¹⁷ cm⁻³; an active layer disposed on the n-type cladding layer and including a quantum well; and a p-type cladding layer of AlGaInP disposed on the active layer.

Accordingly, in the semiconductor laser device according to the present invention, any inactive Si atom is not formed that does not contribute as the carrier in the n-type cladding layer, there are less atoms of the group 3 kicked out of the n-AlGaAs layer by the inactive Si atoms, and the inactivation is inhibited with respect to the p-type impurities of the p-type layer by the atoms of the group 3 between the lattices.

Therefore, an operating current is retained at a low value, a property at room temperature becomes satisfactory, and a high-efficiency operation is possible. Consequently, there can be provided a semiconductor laser device by which a satisfactory high-temperature and high-output operation is possible and whose reliability is high.

According to still another aspect of the invention, there is provided a semiconductor laser device comprising: a GaAs substrate; an n-type semiconductor layer structure disposed on the GaAs substrate; an n-type cladding layer of AlGaInP including n-type impurities of Si disposed on the n-type semiconductor layer structure, the n-type cladding layer having an n-type carrier concentration in a range of 5×10¹⁶ cm⁻³ or more and less than 3×10¹⁷ cm⁻³; an active layer disposed on the n-type cladding layer and including a quantum well; and a p-type cladding layer of AlGaInP disposed on the active layer.

Accordingly, in the semiconductor laser device according to the present invention, any inactive Si atom is not formed that does not contribute as the carrier in the n-type cladding layer, there are less atoms of the group 3 kicked out of the n-AlGaAs layer by the inactive Si atoms, and the inactivation is inhibited with respect to the p-type impurities of the p-type layer by the atoms of the group 3 between the lattices.

Therefore, an operating current is retained at a low value, a property at room temperature becomes satisfactory, and a high-efficiency operation is possible. Consequently, there can be provided a semiconductor laser device by which a satisfactory high-temperature and high-output operation is possible and whose reliability is high.

Other objects and advantages of the invention will become apparent from the detailed description given hereinafter. It should be understood, however, that the detailed description and specific embodiments are given by way of illustration only since various changes and modifications within the scope of the invention will become apparent to those skilled in the art from this detailed description.

### BRIEF DESCRIPTION OF THE DRAWINGS

FIG. 1 is a perspective view of a semiconductor laser device according to one embodiment of the present invention.

FIG. 2 is a partially sectional view in the vicinity of an active layer of the semiconductor laser device according to one embodiment of the present invention.

FIG. 3 is a graph showing a value of an operating current with respect to the n-type carrier concentration of the n-AlGaAs layer in the semiconductor laser according to one embodiment of the present invention.

FIG. 4 is a graph showing a relation between a flow rate of SiH4 and an n-type carrier concentration of an n-AlGaAs layer in forming the n-AlGaAs layer in the semiconductor laser according to one embodiment of the present invention.

FIG. 5 is a graph showing a value of an operating current with respect to the Si concentration of the n-AlGaAs layer in the semiconductor laser according to one embodiment of the present invention.

FIG. 6 is a perspective view of a modification of the semiconductor laser according to one embodiment of the present invention.

FIG. 7 is a perspective view of a semiconductor laser device according to one embodiment of the present invention.

FIG. 8 is a partially sectional view in the vicinity of an active layer of the semiconductor laser device according to one embodiment of the present invention.

FIG. 9 is a graph showing a value of an operating current with respect to the n-type carrier concentration of the n-AlGaInP layer in the semiconductor laser according to one embodiment of the present invention.

FIG. 10 is a graph showing a relation between a flow rate of SiH4 and an n-type carrier concentration of an n-AlGaInP layer in forming the n-AlGaInP layer in the semiconductor laser according to one embodiment of the present invention.

FIG. 11 is a graph showing a value of the operating current with respect to the Si concentration of the n-AlGaInP layer in the semiconductor laser according to one embodiment of the present invention.

FIG. 12 is a perspective view of a semiconductor laser device according to one embodiment of the present invention.

FIG. 13 is a partially sectional view in the vicinity of an active layer of the semiconductor laser device according to one embodiment of the present invention.

FIG. 14 is a perspective view of a modification of the semiconductor laser device according to one embodiment of the present invention.

In all figures, the substantially same elements are given the same reference numbers.

### DESCRIPTION OF THE PREFERRED EMBODIMENTS

### Embodiment 1

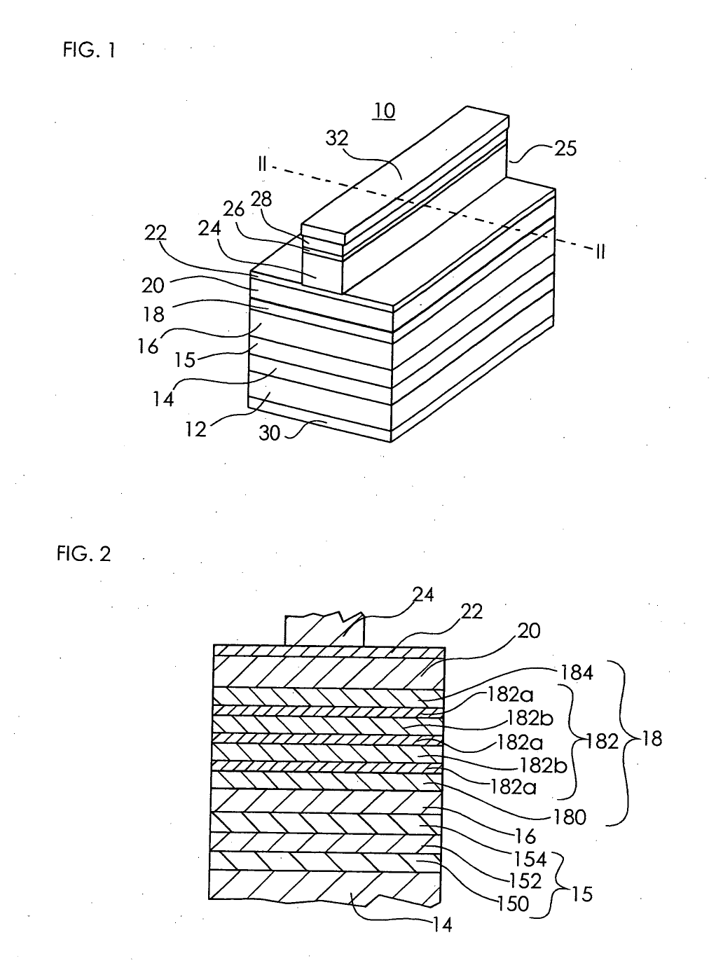

FIG. 1 is a perspective view of a semiconductor laser device according to one embodiment of the present invention, and FIG. 2 is a partially sectional view in the vicinity of an active layer of the semiconductor laser device according to one embodiment of the present invention. In the following figures, the same reference numerals as those of FIGS. 1 and 2 indicate the same or corresponding components.

In FIG. 1, a 650 nm-band ridge-waveguide-type red laser diode (the laser diode is hereinafter abbreviated as LD) 10 is used in a DVD-R/RW device.

The red LD 10 comprises layers successively disposed on an n-GaAs substrate 12: an n-GaAs buffer layer 14; an n-BDR layer 15 used as an n-type semiconductor layer structure; an n-type cladding layer 16 of n-AlGaInP; an active region layer 18; a first p-type cladding layer 20 of p-AlGaInP; a p-ESL layer 22 of p-GaInP; a second p-type cladding layer 24 of p-AlGaInP; a p-BDR layer 26 of p-GaInP; and a cap layer 28 of p-GaAs.

The second p-type cladding layer 24, p-BDR layer 26, and cap layer 28 form a striped ridge 25 extending with a predetermined width on a middle portion of an MQW active layer 144 (described with reference to FIG. 2) in a light waveguide direction. The p-ESL layer 22 extends on opposite sides of the ridge 25, and the first p-type cladding layer 20 is coated with the p-ESL layer 22.

FIG. 2 shows a sectional structure including the active region layer 18 and the n-BDR layer 15. A sectional structure including the active region layer 18 and the n-BDR layer 15 is shown in a sectional view of FIG. 2 in a II-II section of FIG. 1.

In FIG. 2, the active region layer 18 comprises: an active layer 182 having an MQW structure; a first light guide layer 180 of i-AlGaInP disposed between the active layer 182 and the n-type cladding layer 16; and an i-AlGaInP second light guide layer 184 disposed between the active layer 182 and the first p-type cladding layer 20.

That is, the first light guide layer 180 is brought into contact with the n-type cladding layer 16, a well layer 182a of i-GaInP is disposed on the guide layer, and further a barrier layer 182b of i-AlGaInP is disposed on the well layer 182a.

The well layers 182a and the barrier layers 182b are alternately disposed, the second light guide layer 184 is disposed on the well layer 182a which is an uppermost layer, and the first p-type cladding layer 20 is brought into contact with the second light guide layer 184.

The MQW active layer 182 has the well layer 182a whose lattice is matched with the n-GaAs substrate 12 and which is formed of i-GaInP, and the layer is formed in such a manner that a wavelength of photo luminescence of the MQW active layer 182 is 630 to 660 nm in measurement at room temperature.

The n-BDR layer 15 comprises an n-AlGaAs layer 150, an n-GaInP layer 152, and an n-AlGaInP layer 154 which are successively stacked from the side of the n-GaAs substrate 12, and the n-AlGaAs layer 150 having an Al composition ratio x is used, wherein x=0.3 to 0.4 in a general formula of AlxGa1-xAs.

It is to be noted that in the present embodiment, the active layer 182 has the MQW structure, but a single-layer quantum well structure may be used.

In the red LD 10, silicon (Si) is added as n-type impurities, and zinc (Zn) is used as p-type impurities. As the p-type impurities, Mg, Be may be used besides Zn. The n-type and p-type impurities similarly apply to the following embodiment.

Furthermore, impurity concentrations and layer thicknesses of the respective layers of the red LD 10 are approximately as follows.

In the buffer layer 14, the impurity concentration of Si is set, for example, to about 5×10¹⁷ to 2×10¹⁸ cm⁻³, and the layer thickness is about 0.5 to 1.5 μm.

The thickness of the n-BDR layer 15 is about 0.05 to 0.2 μm including the n-AlGaAs layer 150, n-GaInP layer 152, and n-AlGaInP layer 154.

In the n-BDR layer 15, the Si concentration of the n-AlGaAs layer 150 is set to a range of about 0.2E18 cm⁻³ or more and 1.4E18 cm⁻³ or less, preferably 0.2E18 cm⁻³ or more and 0.8E18 cm⁻³ or less. The concentration is set, in terms of n-type carrier concentration, to a range of about 1E17 cm⁻³ or more and 9E17 cm⁻³ or less, preferably 1E17 cm⁻³ or more and 5E17 cm⁻³ or less.

The Si impurity concentration of the n-type cladding layer 16 is about 1E17 cm⁻³ to 1E18 cm⁻³, and the layer thickness is about 1 μm to 3 μm.

In the active region layer 18, the first light guide layer 180 and the second light guide layer 184 have a layer thickness of about 10 nm to 100 nm, the barrier layer 182b has a layer thickness of about 3 nm to 10 nm, and the well layer 182a has a layer thickness of about 5 nm to 10 nm. Basically, any impurity is not added to the active region layer 18.

In the first p-type cladding layer 20, the impurity concentration of Zn is about 5E17 cm⁻³ to 2E18 cm⁻³, and the layer thickness is usually about 0.3 μm to 0.5 μm. In the present embodiment, the first p-type cladding layer 20 has a layer thickness of about 0.4 μm.

In the p-ESL layer 22, the impurity concentration of Zn is about 1E18 cm⁻³ to 3E18 cm⁻³, and the layer thickness is about 0.003 μm to 0.05 μm.

In the second p-type cladding layer 24, the layer thickness is about 1 μm to 3 μm, and the impurity concentration of Zn is about 5E17 cm⁻³ to 2E18 cm⁻³.

In the p-BDR layer 26, the impurity concentration of Zn is about 1E17 cm⁻³ to 3E18 cm⁻³, and the layer thickness is about 0.1 μm.

Since the cap layer 28 also functions as a contact layer, the impurity concentration of Zn is about 1E19 cm⁻³ to 3E19 cm⁻³, and the layer thickness is about 0.1 μm to 0.5 μm.

An n-electrode 30 formed of a metal is disposed on the back surface of the n-GaAs substrate 12, and a p-electrode 32 formed of a metal is disposed on the cap layer 28.

Next, a method of manufacturing the red LD 10 will be schematically described.

First, layers are formed on the n-GaAs substrate 12: an n-GaAs layer used as the buffer layer 14; the n-BDR layer 15 including the n-AlGaAs layer 150, n-GaInP layer 152, and n-AlGaInP layer 154 formed successively from the n-GaAs substrate 12 side; an n-AlGaInP layer used as the n-type cladding layer 16 on the n-BDR layer; an i-AlGaInP layer used as the first light guide layer 180; the MQW active layer 182 including the well layer 182a of i-GaInP and the barrier layer 182b of i-AlGaInP; an i-AlGaInP layer used as the second light guide layer 184; a p-AlGaInP layer used as the first p-type cladding layer 20; a p-GaInP layer used as the p-ESL layer 22; a p-AlGaInP layer used as the second p-type cladding layer 24; a p-GaInP layer used as the p-BDR layer 26; and a p-GaAs layer used as the cap layer 28. These layers are successively stacked on the n-GaAs substrate 12, for example, by an MOCVD or MBE process.

At this time, treatment is performed by MOCVD growth on conditions that a growth temperature is, for example, 700° C., and a growth pressure is, for example, 100 mbar. Examples of a material gas for use in forming the respective layers include, trimethyl indium (TMI), trimethyl gallium (TMG), trimethyl aluminum (TMA), phosphine (PH3), arsine (AsH3), silane (SiH4), diethyl zinc (DEZ) and the like. Flow rates of these material gases are controlled using a mass flow controller (MFC), and a desired composition of each layer is obtained.

Thereafter, by etching, the striped ridge 25 is formed comprising: a p-AlGaInP layer used as the second p-type cladding layer 24; a p-GaInP layer used as the p-BDR layer 26; and a p-GaAs layer used as the cap layer 28. The n-electrode 30 is formed on the back surface of the n-GaAs substrate 12, and the p-electrode 32 is formed on the p-GaAs layer used as the cap layer 28.

Especially, when forming the n-AlGaAs layer 150 of the n-BDR layer 15, an n-type carrier concentration of the n-AlGaAs layer 150 is set to a value between 1E17 cm⁻³ and 9E17 cm⁻³, further preferably 1E17 cm⁻³ and 5E17 cm⁻³. These carrier concentration values are values in a case where a C-V carrier profiler is used, and a measurement frequency is 200 kHz. In terms of the Si concentration, the value is set to a value between 0.2E18 cm⁻³ and 1.4E18 cm⁻³, further preferably 2E17 cm⁻³ and 8E17 cm⁻³.

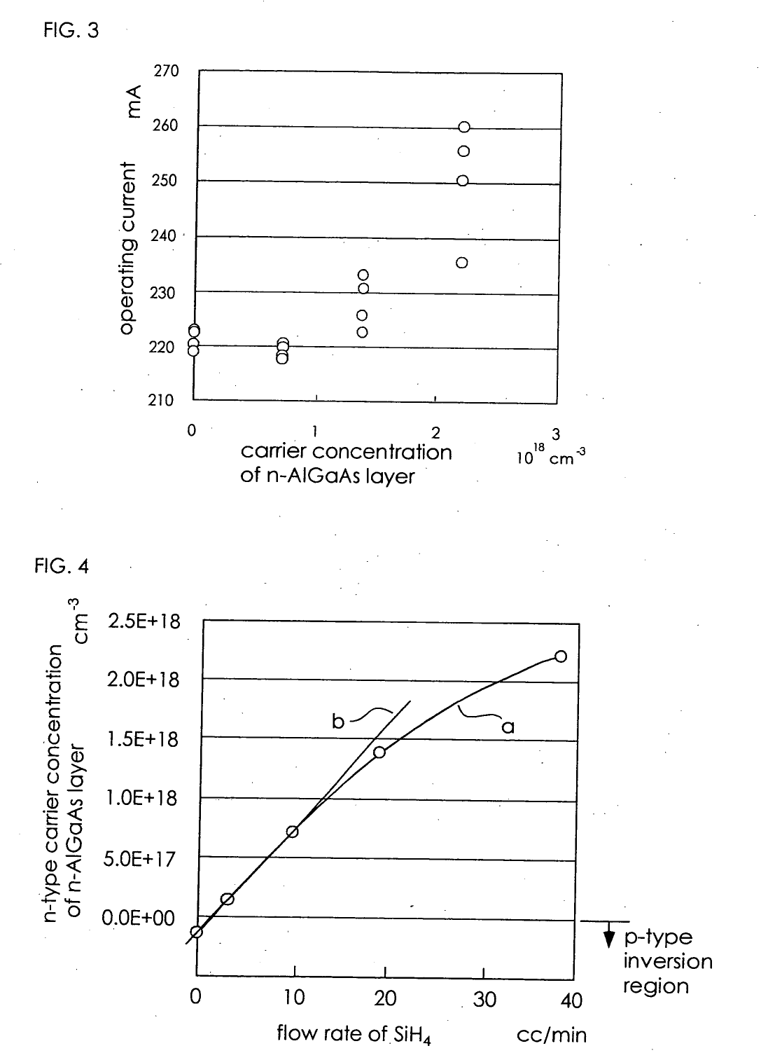

FIG. 3 is a graph showing a value of an operating current with respect to the n-type carrier concentration of the n-AlGaAs layer in the semiconductor laser according to one embodiment of the present invention.

FIG. 4 is a graph showing a relation between a flow rate of SiH4 and an n-type carrier concentration of an n-AlGaAs layer in forming the n-AlGaAs layer in the semiconductor laser according to one embodiment of the present invention.

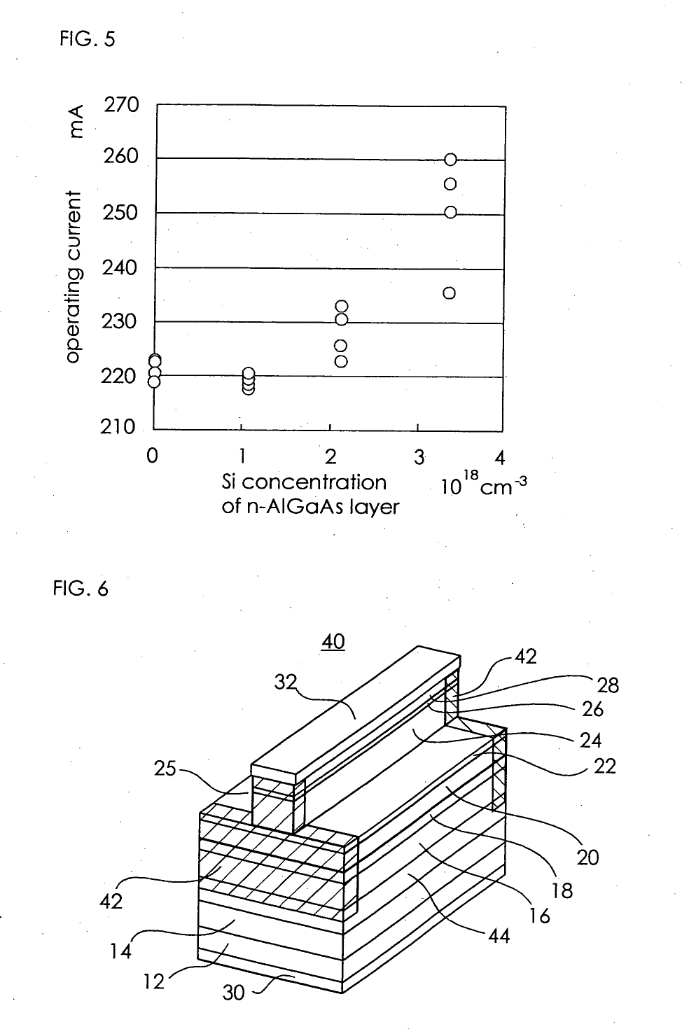

It is to be noted that in FIG. 3, a point indicating a carrier concentration of 0, or a point indicating an Si concentration of 0 (in FIG. 5 described next) indicates that in a state in which the n-BDR layer 15 including the n-AlGaAs layer 150 is not disposed, and in the property of a structure of the only n-GaAs layer constituting the buffer layer 14, the Si concentration of the n-AlGaAs layer is lowered. Accordingly, the same property is obtained as that of a structure which does not include the corresponding layer.

Moreover, FIG. 5 is a graph showing a value of an operating current with respect to the Si concentration of the n-AlGaAs layer in the semiconductor laser according to one embodiment of the present invention.

In FIG. 3, the n-AlGaAs layer 150 is formed of Al0.5Ga0.5As. The n-type carrier concentration was measured in a system in which the etching by an electrolytic solution was not performed, and a surface contact type C-V carrier profiler using a mercury electrode was used.

Measurement conditions include a measurement frequency of 200 kHz, a permittivity of 11.05, an electrode area of 0.467 mm², and an applied voltage of 0 V to −3 V.

In the graph of FIG. 3, when the carrier concentration of the n-AlGaAs layer exceeds the vicinity of 9E17 cm⁻³, an increase of the operating current is recognized.

When collating FIGS. 3 and 4, the vicinity of the n-type carrier concentration of 9E17 cm⁻³ agrees with a region where an SiH4 doping property of the n-AlGaAs layer starts losing linearity, that is, a region where a curve a indicating the measured value of the n-type carrier concentration starts departing from a straight line b in FIG. 4. This means that any Si atom does not enter a lattice position of an atom of the group 3 in a crystal of AlGaAs, and inactive Si starts to be generated which does not contribute as a carrier. Moreover, this indicates that inactive Si further increases, when a flow rate of SiH4 further increases.

Therefore, from FIGS. 3 and 4, when the n-type carrier concentration is in the vicinity of 9E17 cm⁻³ or more, inactive Si increases which does not contribute as the carrier, and accordingly the operating current of the semiconductor laser increases. This reason is supposed as follows.

For example, it has been described in a cited document of Japanese Patent Application Laid-Open No. 2001-237496 ([0041] to [0050]), Journal of Crystal growth vol. 145 (1994) p. 808 to 812 that interstitial atoms of Ga (hereinafter “interstitial atoms of Ga” is referred to as “interstitial Ga”) between lattices in Si-doped GaAs increases with the increase of the Si carrier concentration. Since Ga is a host element of this system, interstitial Ga has a high diffusion speed, and easily diffuses in Zn-doped AlGaAs. By diffused interstitial Ga, Zn in Ga site of Zn-doped AlGaAs is kicked out of Zn-doped AlGaAs to form interstitial atoms of Zn between lattices, and interstitial atoms of Zn diffuse into a layer in the vicinity.

In the Japanese Patent Application Laid-Open No. 2001-237496, Si is used as the n-type dopant, and an n-GaAs substrate is used whose Si impurity concentration is 0.1E17 or more and 1.5E18 or less. In Embodiment 1, the semiconductor laser 10 specifies the Si carrier concentration of an epitaxial crystal of AlGaAs. In the constitution, the n-type carrier concentration of the n-AlGaAs layer 150 is specified. The constitution of Embodiment 1 is different from that of the semiconductor laser of the Japanese Patent Application Laid-Open No. 2001-237496. However, it is considered that inactivation of the p-type impurities in the p-type layer is caused by a mechanism described in a similar diffusion model.

That is, in a situation in which a carrier activation ratio is low, the n-AlGaAs layer is much doped with Si. Then, any Si atom does not enter the lattice position of the atoms of the group 3, and a large number of Si impurities are generated which do not contribute as the carrier. The inactive Si atoms kick out the atoms of the group 3 from the n-AlGaAs layer. For example, here Ga atoms are kicked out of the lattice position, the kicked-out atoms of the group 3 diffuse in the p-type layer to kick out the p-type impurities from the lattice position, and the p-type impurities are inactivated. Moreover, a rise of operating current is caused by the inactivation of the p-type impurities.

Therefore, to prevent the rise of the operating current, it is important to suppress formation of inactive Si which is a cause for the inactivation of the p-type impurities. To attain this, the inactive Si atoms should not be formed which do not contribute as the carrier in n-AlGaAs having a low activation ratio, and the n-type carrier concentration is set to the vicinity of 7E17 cm⁻³ or less.

Based on this consideration, in Embodiment 1, the n-type carrier concentration of the n-AlGaAs layer 150 is set to a value of 1E17 cm⁻³ or more and 7E17 cm⁻³ or less, further preferably 1E17 cm⁻³ or more and 4E17 cm⁻³ or less.

It is to be noted that the n-type carrier concentration of 1E17 cm⁻³ or more is a lower-limit value to such an extent that an element resistance does not increase.

Moreover, the value of the operating current with respect to the Si concentration of FIG. 5 is converted from FIG. 3.

A converting method will be described. In FIG. 3, a sample of n-AlGaAs was subjected to SIMS measurement in an n-type carrier concentration range in which an SiH4 doping property did not lose linearity, measurement was calibrated by a standard sample, and correspondence was confirmed between the n-type carrier concentration and the Si concentration. An Si activation ratio defined by the Si concentration with respect to the n-type carrier concentration, that is, a value of Si activation ratio (=n-type carrier concentration/Si concentration) was calculated. The n-type carrier concentration was converted into the Si concentration using the silicon activation ratio. Additionally, in this case, the Si activation ratio of the n-AlGaAs layer was 65%.

By the use of the value indicating the Si activation ratio of 65%, the above-described value of the n-type carrier concentration of the n-AlGaAs layer 150 of FIG. 3 is converted into the above-described value of the Si concentration in FIG. 5.

It is to be noted that in FIG. 5, the conversion is based on the assumption that the silicon activation ratio is constant at 65%. It is supposed that the conversion indicates the corresponding Si concentration in a region where the SiH4 doping property does not lose its linearity, and the carrier concentration is 1.4E18 cm⁻³ or less. However, the Si activation ratio drops in a region where the Si concentration exceeds 1.4E18 cm⁻³, and therefore the Si concentration is supposed to shift from the graph of FIG. 5.

In the red LD 10 of Embodiment 1, as to the n-AlGaAs layer 150 included in the n-BDR layer 15, the n-type carrier concentration is set to a value of 1E17 cm⁻³ or more and 9E17 cm⁻³ or less, further preferably 1E17 cm⁻³ or more and 5E17 cm⁻³ or less. Alternatively, the Si concentration is set to a value of 0.2E18 cm⁻³ or more and 1.4E18 cm⁻³ or less, further preferably a value of 2E17 cm⁻³ or more and 8E17 cm⁻³ or less. Therefore, any inactive Si atom is not formed that does not contribute as the carrier. Therefore, the atoms of the group 3 have less opportunities of being kicked out of the lattice position in the n-AlGaAs crystal. There is a reduced possibility that atoms of the group 3 kicked out of the n-AlGaAs layer diffuse in the p-type layer to kick out the p-type impurities of the p-type layer, and the p-type impurities are inactivated. Therefore, the operating current is retained at a low value, a property at room temperature becomes satisfactory, and a high-efficiency operation is possible. Therefore, there can be provided a semiconductor laser device by which a satisfactory high-temperature and high output operation is possible and whose reliability is high.

Modification 1

FIG. 6 is a perspective view of a modification of the semiconductor laser according to one embodiment of the present invention.

In FIG. 6, a red LD 40 is different from the red LD 10 in that a window layer 42 obtained by disordering a well layer 182a of an active layer 182 is disposed in the vicinity of a facet formed as a front or rear end face of an optical waveguide including the active layer 182, and an Si-doped n-AlGaAs buffer layer 44 is disposed as an n-type semiconductor layer structure instead of an n-BDR layer 15 of the red LD 10. The n-AlGaAs buffer layer 44 is disposed between the n-type cladding layer 16 and the buffer layer 14 of n-GaAs.

The n-AlGaAs buffer layer 44 has a layer thickness of about 0.2 to 1 μm. As to a carrier concentration or an Si concentration, in the same manner as in the n-AlGaAs layer 150 of Embodiment 1, the n-type carrier concentration is set to a value of 1E17 cm⁻³ or more and 9E17 cm⁻³ or less, further preferably 1E17 cm⁻³ or more and 5E17 cm⁻³ or less, or the Si concentration is set to a value between 0.2E18 cm⁻³ or more and 1.4E18 cm⁻³ or less, further preferably 2E17 cm⁻³ or more and 8E17 cm⁻³ or less.

When forming the window layer, Zn disorders the well layer of the active layer and further diffuses in the n-type layer on an n-type GaAs substrate side. An object in which the n-AlGaAs buffer layer 44 is disposed is to prevent Zn from being diffused up to the n-GaAs buffer layer.

If Zn diffuses up to the n-GaAs buffer layer, p-n bonding is formed in the n-GaAs buffer layer.

Usually, a forward-direction rising voltage Vf of the semiconductor laser is determined by band gap energy of an MQW active layer. However, since the band gap energy of the n-GaAs buffer layer is smaller than that of the MQW active layer, first the device turns on by the p-n bonding of a window region, the forward-direction rising voltage Vf decreases, and a leak current is caused. A property of the semiconductor laser is adversely affected by the leak current depending on the circumstances. To solve the problem, the second buffer layer is formed of n-AlGaAs whose Zn diffusion speed is low as compared with AlGaInP forming the n-cladding layer, the diffusion of Zn is stopped, and current leakage is prevented.

Next, a method of manufacturing the red LD 40 will be described.

First, layers are formed successively on the n-GaAs substrate 12: an n-GaAs layer used as a buffer layer 14; an n-AlGaAs layer used as the buffer layer 44; an n-AlGaInP layer used as an n-type cladding layer 16; an i-AlGaInP layer used as a first light guide layer 180; an MQW active layer 182 including a well layer 182a of i-GaInP and a barrier layer 182b of i-AlGaInP; an i-AlGaInP layer used as a second light guide layer 184; a p-AlGaInP layer used as a first p-type cladding layer 20; a p-GaInP layer used as a p-ESL layer 22; a p-AlGaInP layer used as a second p-type cladding layer 24; a p-GaInP layer used as a p-BDR layer 26; and a p-GaAs layer used as a cap layer 28. These layers are successively stacked on the n-GaAs substrate 12, for example, by an MOCVD or MBE process in the same manner as in Embodiment 1.

Next, ZnO is evaporated in the vicinity of a facet formed as a front or rear end face of an optical waveguide including the MQW active layer 182, Zn is diffused from the surface of the p-GaAs layer forming the cap layer 28 by annealing, and the well layer 182a of the MQW active layer 182 is disordered in the vicinity of the front and rear end faces to form the window layer 42.

Thereafter, by etching, the striped ridge 25 is formed comprising: a p-AlGaInP layer used as the second p-type cladding layer 24; a p-GaInP layer used as the p-BDR layer 26; and a p-GaAs layer used as the cap layer 28. The n-electrode 30 is formed on the back surface of the n-GaAs substrate, and the p-electrode 32 is formed on the p-GaAs layer used as the cap layer 28.

Also in the red laser 40 having the window layer 42 of the present modification, an n-type carrier concentration of the buffer layer 44 of n-AlGaAs is set to a value of 1E17 cm⁻³ or more and 9E17 cm⁻³ or less, further preferably 1E17 cm⁻³ or more and 5E17 cm⁻³ or less. Alternatively, an Si concentration is set to a value between 0.2E18 cm⁻³ and 1.4E18 cm⁻³, further preferably 2E17 cm⁻³ and 8E17 cm⁻³. Therefore, any inactive Si atom is not formed that does not contribute as the carrier. Therefore, atoms of the group 3 have less opportunities of being kicked out of a lattice position in an n-AlGaAs crystal. There is a reduced possibility that the atoms of the group 3 kicked out of the n-AlGaAs layer diffuse in the p-type layer to kick out p-type impurities of the p-type layer, and the p-type impurities are inactivated. Therefore, an operating current is retained at a low value, a property at room temperature becomes satisfactory, and a high-efficiency operation is possible. Therefore, there can be provided a semiconductor laser device by which a satisfactory high-temperature and high-output operation is possible and whose reliability is high.

As described above, the semiconductor laser device according to Embodiment 1 comprises: the GaAs substrate; the n-type semiconductor layer structure disposed on the GaAs substrate, and including the AlGaAs layer whose concentration of Si doped as n-type impurities is in a range of 0.2E18 cm⁻³ to 1.4E18 cm⁻³ or the AlGaAs layer whose n-type carrier concentration is in a range of 1E17 cm⁻³ to 9E17 cm⁻³; the n-type cladding layer disposed on the n-type semiconductor layer structure and formed of AlGaInP; the active layer disposed on the n-type cladding layer and including the quantum well; and the p-type cladding layer of AlGaInP disposed on the active layer. In the n-AlGaAs layer, any inactive Si atom is not formed that does not contribute as the carrier. Less atoms of the group 3 are kicked out of the n-AlGaAs layer by the inactive Si atoms, and the inactivation is inhibited with respect to the p-type impurities of the p-type layer by the atoms of the group 3 between the lattices.

Therefore, an operating current is retained at a low value, a property at room temperature becomes satisfactory, and a high-efficiency operation is possible. Consequently, there can be provided a semiconductor laser device by which a satisfactory high-temperature and high-output operation is possible and whose reliability is high.

Moreover, the semiconductor laser device according to Embodiment 1 further comprises the window layer which is disposed in the vicinity of the opposite end faces of the optical waveguide including the active layer and whose active layer is disordered by the p-type impurities. Therefore, there can be provided a semiconductor laser device whose operating current is low and in which the high-efficiency operation is possible and in which the window layer capable of performing the satisfactory high-temperature and high-output operation is disposed. Additionally, there can be provided a semiconductor laser device whose reliability is high.

### Embodiment 2

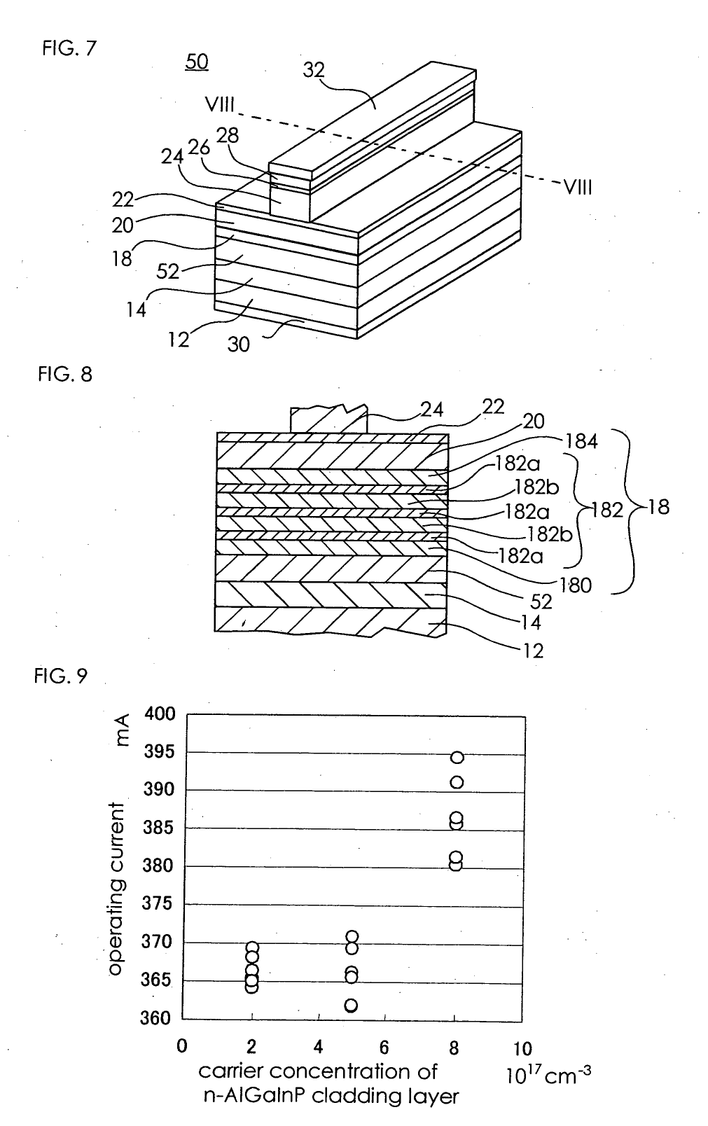

FIG. 7 is a perspective view of a semiconductor laser device according to one embodiment of the present invention, and FIG. 8 is a partially sectional view in the vicinity of an active layer of the semiconductor laser device according to one embodiment of the present invention. It is to be noted that FIG. 8 is a sectional view in a VIII-VIII section in FIG. 7.

In Embodiment 1, between an n-type cladding layer and an n-GaAs buffer layer, an AlGaAs layer is disposed whose carrier concentration is of such a degree that inactive Si is not easily generated. Accordingly, inactivation of p-type impurities of a p-type layer is inhibited, and a rise of an operating current is suppressed. In the present embodiment, an n-type cladding layer formed of AlGaInP is set to a carrier concentration such that inactive Si is not easily generated. Accordingly, the inactivation of the p-type impurities of the p-type layer is inhibited, and the rise of the operating current is suppressed.

In FIG. 7, a red LD 50 comprises layers successively disposed on an n-GaAs substrate 12: an n-GaAs buffer layer 14 used as an n-type semiconductor layer structure; an n-type cladding layer 52 of n-AlGaInP; an active region layer 18; a first p-type cladding layer 20 of p-AlGaInP; a p-ESL layer 22 of p-GaInP; a second p-type cladding layer 24 of p-AlGaInP; a p-BDR layer 26 of p-GaInP; and a cap layer 28 of p-GaAs.

The second p-type cladding layer 24, p-BDR layer 26, and cap layer 28 form a striped ridge 25 extending with a predetermined width on a middle portion of an MQW active layer 144 in a light waveguide direction. The p-ESL layer 22 is exposed on opposite sides of the ridge 25, and the first p-type cladding layer 20 is coated with the p-ESL layer 22.

FIG. 8 shows a sectional structure including the active region layer 18 and the n-type cladding layer 52. A sectional structure including the active region layer 18 and the n-type cladding layer 52 is shown in a sectional view of FIG. 8 in a VIII-VIII section of FIG. 1.

In FIG. 8, the buffer layer 14 uses GaAs, but may be formed of GaInP, AlGaAs or the like.

The thickness of the n-type cladding layer 52 formed of n-AlGaInP is about 1 μm to 3 μm in the same manner as in the red LD 10 of Embodiment 1, but an n-type carrier concentration or Si concentration is different from that of the red LD 10.

That is, in the n-type cladding layer 52, the n-type carrier concentration of an n-AlGaInP layer is set to a range of about 0.5E17 cm⁻³ or more and 4E17 cm⁻³ or less. In consideration of fluctuations of data, the concentration is set to a range of preferably 0.5E17 cm⁻³ or more and less than 3E17 cm⁻³, further preferably 0.5E17 cm⁻³ or more and less than 2E17 cm⁻³.

Alternatively, in terms of an Si concentration, the Si concentration of the n-AlGaInP layer is set to a range of about 0.6E17 cm⁻³ or more and 4.4E17 cm⁻³ or less. In consideration of the fluctuations of data, the concentration is set to a range of preferably 0.6E17 cm⁻³ or more and less than 3.3E17 cm⁻³, further preferably 0.6E17 cm⁻³ or more and less than 2.2E17 cm⁻³. A constitution of another layer in the red LD 50 is similar to that of the red LD 10 of Embodiment 1.

Moreover, a method of manufacturing the red LD 50 is similar to that of the red LD 10. However, when forming the n-AlGaInP layer constituting the n-type cladding layer 52, the n-type carrier concentration or the Si concentration of the n-AlGaInP layer is set to the above-described value. This value of the carrier concentration is a value in a case where a C-V carrier profiler is used, and a measurement frequency is 10 kHz.

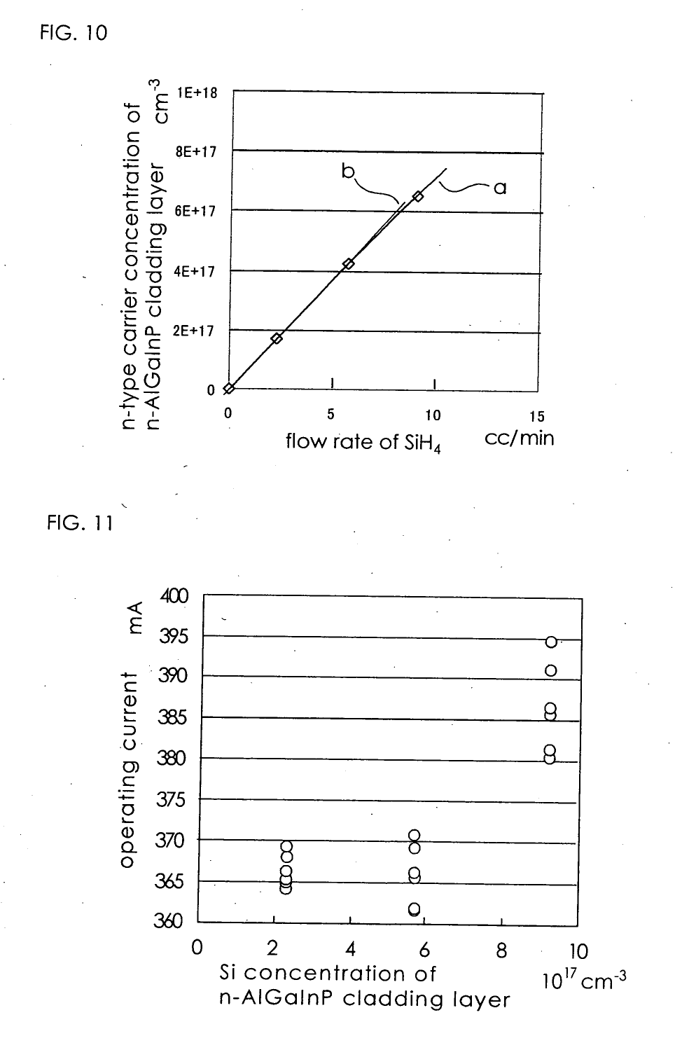

FIG. 9 is a graph showing a value of an operating current with respect to the n-type carrier concentration of the n-AlGaInP layer in the semiconductor laser according to one embodiment of the present invention. FIG. 10 is a graph showing a relation between a flow rate of SiH4 and an n-type carrier concentration of an n-AlGaInP layer in forming the n-AlGaInP layer in the semiconductor laser according to one embodiment of the present invention. FIG. 11 is a graph showing a value of the operating current with respect to the Si concentration of the n-AlGaInP layer in the semiconductor laser according to one embodiment of the present invention.

In FIGS. 9 and 10, the n-type cladding layer 52 is formed of (Al0.7Ga0.3)0.5In0.5P. The n-type carrier concentration was measured in a system in which the etching by an electrolytic solution was not performed, and a surface contact type C-V carrier profiler using a mercury electrode was used. Measurement conditions include a measurement frequency of 10 kHz, a permittivity of 11.75, an electrode area of 0.467 mm², and an applied voltage of 0 V to −3 V.

In the graph of FIG. 9, when the carrier concentration of the n-AlGaInP layer forming the n-type cladding layer 52 exceeds 4E17 cm⁻³, an increase of the operating current is recognized.

When collating FIGS. 9 and 10, a region in the vicinity of the n-type carrier concentration of 4E17 cm⁻³ agrees with a region where an SiH4 doping property of the n-AlGaInP layer starts losing linearity, that is, a region where a curve a indicating the measured value of the n-type carrier concentration starts departing from a straight line b. This means that any Si atom does not enter a lattice position of an atom of the group 3 in a crystal of AlGaInP, and inactive Si starts to be generated which does not contribute as a carrier. Although FIG. 10 shows only data of the region of SiH4 that is not very large, it is supposed that inactive Si further increases, when a flow rate of SiH4 further increases.

Therefore, from FIGS. 9 and 10, as to the n-AlGaInP layer used as the n-cladding layer, when the n-type carrier concentration is in the vicinity of 4E17 cm⁻³ or more, inactive Si increases which does not contribute as the carrier, and accordingly the operating current of the semiconductor laser increases. This reason is supposed to be similar to that described in Embodiment 1.

Therefore, to prevent the rise of the operating current, it is important to inhibit the formation of inactive Si. To attain this, the inactive Si atoms should not be formed which do not contribute as the carrier in the n-AlGaInP layer forming the n-cladding layer having a low activation ratio, and the n-type carrier concentration is set to the vicinity of 4E17 cm⁻³ or less.

Based on this consideration, in Embodiment 2, the n-type carrier concentration of the n-type cladding layer 52 of n-AlGaInP is set to a value of 0.5E17 cm⁻³ or more and 4E17 cm⁻³ or less. In consideration of fluctuations of data, the concentration is set to a range of preferably about 0.5E17 cm⁻³ or more and less than 3E17 cm⁻³, further preferably 0.5E17 cm⁻³ or more and less than 2E17 cm⁻³.

It is to be noted that the n-type carrier concentration of 0.5E17 cm⁻³ or more is a lower-limit value to such an extent that an element resistance does not increase.

Moreover, the value of the operating current with respect to the Si concentration of FIG. 11 is converted from FIG. 9. A converting method is similar to that described in Embodiment 1. In this case, the Si activation ratio of the n-AlGaInP layer was 90%. By the use of the value indicating the Si activation ratio of 90%, the n-type carrier concentration of the n-AlGaInP layer of the n-type cladding layer 52 of FIG. 9 is converted into the value of the Si concentration in FIG. 11.

It is to be noted that in FIG. 11, the conversion is based on the assumption that the silicon activation ratio is constant at 90%. It is supposed that the conversion indicates the corresponding Si concentration in a region where the SiH4 doping property does not lose its linearity, and the carrier concentration is 4E17 cm⁻³ or less. However, the Si activation ratio drops in a region where the Si concentration exceeds 4E17 cm⁻³, and therefore the Si concentration is supposed to shift from the graph of FIG. 11.

In the red LD 50 of Embodiment 2, as to the n-AlGaInP layer of the n-type cladding layer 52, the n-type carrier concentration is set to a range of about 0.5E17 cm⁻³ or more and 4E17 cm⁻³ or less. In consideration of the fluctuations of data, the concentration is set to a range of preferably 0.5E17 cm⁻³ or more and less than 3E17 cm⁻³, further preferably 0.5E17 cm⁻³ or more and less than 2E17 cm⁻³. Alternatively, in terms of the Si concentration, the Si concentration of the n-AlGaInP layer is set to a range of about 0.6E17 cm⁻³ or more and 4.4E17 cm⁻³ or less. In consideration of the data fluctuations, the concentration is set to a range of preferably 0.6E17 cm⁻³ or more and less than 3.3E17 cm⁻³, further preferably 0.6E17 cm⁻³ or more and less than 2.2E17 cm⁻³. Therefore, any inactive Si atom is not formed that does not contribute as the carrier. Therefore, there is less possibility that the inactive Si atoms kick out the atoms of the group 3 from the lattice position in the n-AlGaAs layer. There is a reduced possibility that atoms of the group 3 kicked out of the n-AlGaAs layer diffuse in the p-type layer to kick out the p-type impurities of the p-type layer, and the p-type impurities are inactivated.

Therefore, the operating current is retained at a low value, a property at room temperature becomes satisfactory, and a high-efficiency operation is possible. Therefore, there can be provided a semiconductor laser device by which a satisfactory high-temperature and high-output operation is possible and whose reliability is high.

It is to be noted that also in Embodiment 2, in the same manner as in Modification 1 of Embodiment 1, the red LD may comprise: the n-AlGaAs buffer layer disposed between the n-type cladding layer 52 and the n-GaAs buffer layer 14; and the window layer 42 disposed in the vicinity of the facet formed as the front or rear end face of the optical waveguide including the active layer 182 and obtained by disordering the well layer 182a of the active layer 182. Accordingly, there can be provided the red LD whose operating current is low and in which a high-efficiency operation is possible and whose window layer is capable of performing a satisfactory high-temperature and high-output operation.

As described above, the semiconductor laser device according to Embodiment 2 comprises: the GaAs substrate; the n-type semiconductor layer structure disposed on the GaAs substrate; and the n-type cladding layer disposed on the n-type semiconductor layer structure and formed of AlGaInP. In the n-type cladding layer, the n-type impurities is Si, and the Si concentration is in a range of 0.6E17 cm⁻³ or more and less than 3.3E17 cm⁻³, or the n-type carrier concentration is 0.5E17 cm⁻³ or more and less than 3E17 cm⁻³. The device further comprises: the active layer disposed on this n-type cladding layer and including the quantum well; and the p-type cladding layer of AlGaInP disposed on the active layer. Any inactive Si atom is not formed that does not contribute as the carrier in the n-type cladding layer, there are less atoms of the group 3 kicked out of the n-AlGaAs layer by the inactive Si atoms, and the inactivation is inhibited with respect to the p-type impurities of the p-type layer by the atoms of the group 3 between the lattices. Therefore, the operating current is retained at a low value, a property at room temperature becomes satisfactory, and a high-efficiency operation is possible. Therefore, there can be provided a semiconductor laser device by which a satisfactory high-temperature and high-output operation is possible and whose reliability is high.

Moreover, further the window layer is disposed which is disposed in the vicinity of the opposite end faces of the optical waveguide including the active layer and whose active layer is disordered by the n-type impurities. There can be provided a semiconductor laser device whose operating current is low and in which a high-efficiency operation is possible and whose window layer is capable of performing a satisfactory high-temperature and high-output operation. Consequently, there can be provided a semiconductor laser device including the window layer and having a high reliability.

### Embodiment 3

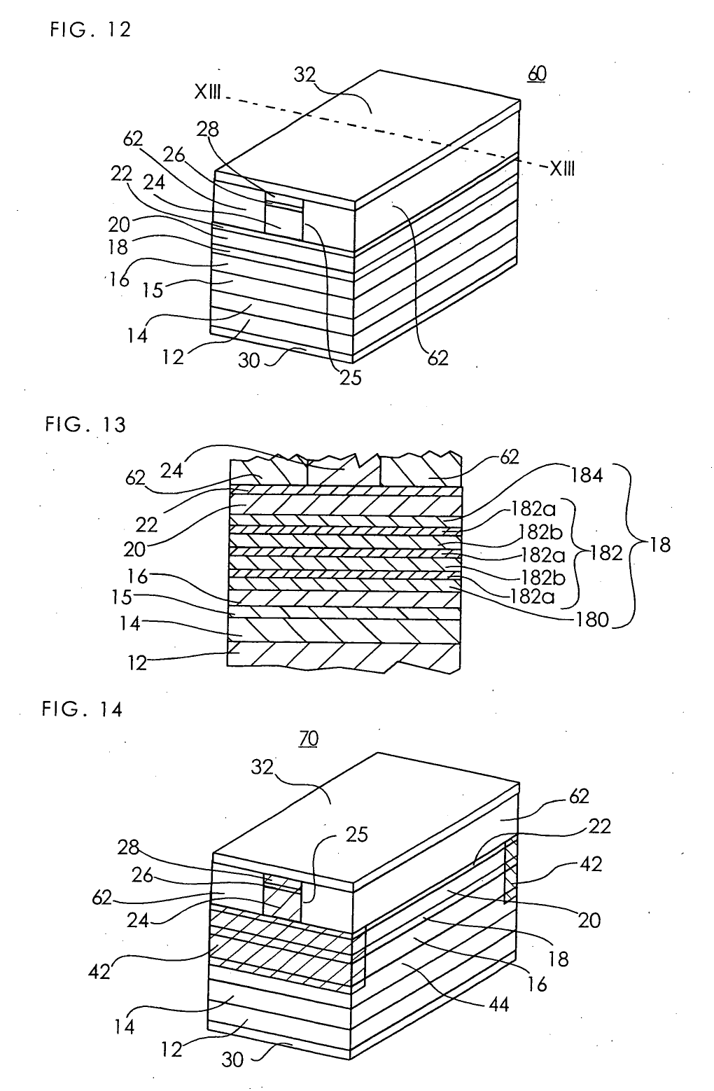

FIG. 12 is a perspective view of a semiconductor laser device according to one embodiment of the present invention, and FIG. 13 is a partially sectional view in the vicinity of an active layer of the semiconductor laser device according to one embodiment of the present invention. It is to be noted that FIG. 13 is a sectional view in a XIII-XIII section in FIG. 12.

Moreover, FIG. 14 is a perspective view of a modification of the semiconductor laser device according to one embodiment of the present invention.

In a ridge-buried type red LD 60 shown in FIGS. 12 and 13, a ridge 25 has a current constricted structure in which a current constricting layer 62 is buried comprising an n-type semiconductor layer structure, an insulator layer and the like. A constitution of another layer is similar to that of the semiconductor LD 10.

Even the ridge-buried type red LD 60 produces an effect similar to that of the ridge waveguide type semiconductor LD 10.

Moreover, in a ridge-buried type red LD 70 shown in FIG. 14, a ridge 25 has a current constricted structure in which a current constricting layer 62 is buried comprising an n-type semiconductor layer structure, an insulator layer and the like. A constitution of another layer is similar to that of the semiconductor LD 40

Even the ridge-buried type red LDs 60 and 70 produce effects similar to those of the ridge waveguide type red LDs 10 and 40.

It is to be noted that in the present embodiment, it has been described that the constitution of each layer other than the current constricted structure is similar to that of the red LD of Embodiment 1. The constitution of each layer other than the current constricted structure may be constituted as described in Embodiment 2. In this case, an effect similar to that of Embodiment 2 is produced.

As described above, a semiconductor laser device of the present invention is suitable for a semiconductor laser device for use in an information communication apparatus.

While the presently preferred embodiments of the present invention have been shown and described. It is to be understood these disclosures are for the purpose of illustration and that various changes and modifications may be made without departing from the scope of the invention as set forth in the appended claims.

1. A semiconductor laser device comprising:
a GaAs substrate;
an n-type semiconductor layer structure disposed on the GaAs substrate, including an AlGaAs layer doped with Si, the AlGaAs layer having a concentration of Si in a range from 0.2×10¹⁸ cm⁻³ to 1.4×10¹⁸ cm⁻³;
an n-type cladding layer of AlGaInP disposed on the n-type semiconductor layer structure;
an active layer disposed on the n-type cladding layer, and including a quantum well; and
a p-type cladding layer of AlGaInP disposed on the active layer.

2. A semiconductor laser device comprising:
a GaAs substrate;
an n-type semiconductor layer structure disposed on the GaAs substrate, including an AlGaAs layer doped with Si, the AlGaAs layer having n-type carrier concentration in a range from 1×10¹⁷ cm⁻³ to 9×10¹⁷ cm⁻³; can n-type cladding layer of AlGaInP disposed on the n-type semiconductor layer structure;
an active layer disposed on the n-type cladding layer and including a quantum well; and
a p-type cladding layer of AlGaInP disposed on the active layer.

3. A semiconductor laser device comprising:
a GaAs substrate;
an n-type semiconductor layer structure disposed on the GaAs substrate;
an n-type cladding layer of AlGaInP containing Si and disposed on the n-type semiconductor layer structure, the n-type cladding layer having a concentration of Si in a range from 0.6×10¹⁷ cm⁻³ to less than 3.3×10¹⁷ cm⁻³;
an active layer disposed on the n-type cladding layer and including a quantum well; and
a p-type cladding layer of AlGaInP disposed on the active layer.

4. A semiconductor laser device comprising:
a GaAs substrate;
an n-type semiconductor layer structure disposed on the GaAs substrate;
an n-type cladding layer of AlGaInP containing Si and disposed on the n-type semiconductor layer structure, the n-type cladding layer having an n-type carrier concentration in a range from 5×10¹⁶ cm⁻³ to less than 3×10¹⁷ cm⁻³;
an active layer disposed on the n-type cladding layer and including a quantum well; and
a p-type cladding layer of AlGaInP disposed on the active layer.

5. The semiconductor laser device according to claim 1, further comprising a window layer disposed proximate opposite end faces of an optical waveguide including the active layer, wherein the active layer within the window layer is disordered by p-type impurities.

6. The semiconductor laser device according to claim 2, further comprising a window layer disposed proximate opposite end faces of an optical waveguide including the active layer, wherein the active layer within the window layer is disordered by p-type impurities.

7. The semiconductor laser device according to claim 3, further comprising a window layer disposed proximate opposite end faces of an optical waveguide including the active layer, wherein the active layer within the window layer is disordered by p-type impurities.

8. The semiconductor laser device according to claim 4, further comprising a window layer disposed proximate opposite end faces of an optical waveguide including the active layer, wherein the active layer within the window layer is disordered by p-type impurities.
